(19) United States
(12) Patent Application Publication
(10) Pub. No.: US 2025/0266793 A1
(43) Pub. Date: Aug. 21, 2025

(54) MODULE, APPARATUS, METHOD, AND NON-TRANSITORY COMPUTER READABLE STORAGE MEDIUM FOR LINEAR POWER-AMPLIFICATION USING CLASS-AB POWER AMPLIFIERS

(71) Applicant: Huawei Technologies Co., Ltd., Shenzhen (CN)

(72) Inventors: Guohui Situ, Kanata (CA); Samuel Alfred Tiller, Ottawa (CA)

(21) Appl. No.: 19/202,671

(22) Filed: May 8, 2025

Related U.S. Application Data
(63) Continuation of application No. PCT/CN2023/071459, filed on Jan. 9, 2023.

(51) Int. Cl. H03F 1/02; H03F 1/32; H03F 1/56; H03F 3/24

(52) U.S. Cl. CPC H03F 1/0288; H03F 1/3288; H03F 1/56; H03F 3/245; H03F 2200/105

(57) ABSTRACT

A linear power-amplifier module has a splitter for splitting an input signal into a plurality split signals, a plurality of circuit branches connected to the splitter, each circuit branch for receiving one of the plurality of split signals, and an output connected to the plurality of circuit branches for combining outputs of the plurality of circuit branches and outputting an output signal. Each circuit branch is for receiving one of the plurality of split signals, each circuit branch comprises a class-AB PA operable under a biasing voltage, and one or more circuit branches each has a respective control circuit connected to an input of the class-AB PA thereof.

### CROSS-REFERENCE TO RELATED APPLICATION

The present application is a continuation of Patent Cooperation Treaty Application No. PCT/CN2023/071459, entitled “MODULE, APPARATUS, METHOD, AND NON-TRANSITORY COMPUTER READABLE STORAGE MEDIUM FOR LINEAR POWER-AMPLIFICATION USING CLASS-AB POWER AMPLIFIERS,” filed on Jan. 9, 2023, the entirety of which is incorporated by reference herein.

### TECHNICAL FIELD

The present disclosure relates generally to module, apparatus, method, and non-transitory computer readable storage medium for linear power-amplification, and in particular to module, apparatus, method, and non-transitory computer readable storage medium for linear power-amplification using class-AB power amplifiers.

### BACKGROUND

Wireless communication systems such as millimeter-wave (mmWave) fifth-generation (5G) systems, sixth-generation (6G) systems, and the like typically employ phase arrays with high-order quadrature amplitude modulations (QAMs) to overcome the high path-loss of free space and to provide high data-throughput and low latency. Such systems often require amplitude adjustment and/or reduction of power levels of signals to facilitate beam shaping. However, the low and variable power levels may reduce the operation efficiency and make the designing of the systems under a fixed, maximum power requirement inefficient.

The complex QAM signals usually have high peak-to-average power ratio (PAPR), which may cause power amplifiers (PAs) to operate at higher power back-off (PBO) from the peak to maintain linearity, and thus greatly reduce the efficiency at the low output powers for conventional Class-A, Class-AB and Class-B PAs.

### SUMMARY

According to one aspect of this disclosure, there is provided a linear power-amplification module comprising: a splitter for splitting an input signal into a plurality split signals; a plurality of circuit branches connecting to the splitter, each circuit branch for receiving one of the plurality of split signals; and an output connecting to the plurality of circuit branches for combining outputs of the plurality of circuit branches and outputting an output signal; each circuit branch is for receiving one of the plurality of split signals; each circuit branch comprises a class-AB power-amplifier (PA) operable under a biasing voltage; and one or more circuit branches each comprises a respective control circuit connected to an input of the class-AB PA thereof.

In some embodiments, each circuit branch comprises the respective control circuit connected to the input of the respective class-AB PA thereof.

In some embodiments, the one or more control circuits of the one or more circuit branches are configured for adjusting input powers of the class-AB PAs.

In some embodiments, the one or more control circuits of the one or more circuit branches are configured for adjusting the input powers of the class-AB PAs by adjusting power-division percentages of the input powers of the class-AB PAs in accordance with

$${Pin}_{i} = P 1 + 10 {log}_{10} ( {x}_{i} )$$

where P1 is an power proportional to power of the input signal, i=1, 2, . . . , N is the index of the class-AB PAs, N is the total number of the class-AB PAs, Pinᵢ is the input power of the i-th class-AB PA, xᵢ is the power-division percentage of the input power of the i-th class-AB PA, 1≥xᵢ≥0, and Σᵢ₌₁^{N}xᵢ=1.

In some embodiments, the one or more control circuits of the one or more circuit branches are configured for adjusting the biasing voltage of at least one of the class-AB PAs.

In some embodiments, the one or more control circuits of the one or more circuit branches are configured for adjusting the biasing voltage of at least one of the class-AB PAs by adjusting biasing current of the of at least one of the class-AB PAs.

In some embodiments, the one or more control circuits of the one or more circuit branches are configured for applying phase adjustment between input signals of the class-AB PAs of the circuit branches.

In some embodiments, at least one of the one or more control circuits of the one or more circuit branches comprises at least one of an attenuator and one or more adjustment amplifiers.

In some embodiments, the one or more control circuits of the one or more circuit branches are configured for adjusting the input powers of the class-AB PAs by adjusting at least one of an attenuation of the attenuator and biasing voltage of each of the one or more adjustment amplifiers.

In some embodiments, the one or more control circuits of the one or more circuit branches are configured for adjusting the phase shift between the input signals of the class-AB PAs of the circuit branches by adjusting biasing voltage of at least one of the one or more adjustment amplifiers.

In some embodiments, the linear power-amplification module comprises two circuit branches each comprising the respective control circuit connected to the input of the respective class-AB PA thereof.

In some embodiments, the one or more control circuits of the one or more circuit branches are configured for adjusting input powers of the class-AB PAs a parameter r in accordance with

$${Pin}_{m a i n} = P 1 + 10 {log}_{10} ( r )$$

$${Pin}_{p e a k i n g} = P 1 + 10 {log}_{10} ( 1 - r )$$

where P1 is a power proportional to the power of the input signal, Pinₘₐᵢₙ and Pin_{peaking} are the input powers of the two class-AB PAs, respectively, and 1≥r≥0.

In some embodiments, 1≥r≥0.5.

In some embodiments, the two control circuits of the two circuit branches are configured for adjusting the bias voltages of the two class-AB PAs, or for adjusting the biasing voltage of a peaking PA of the two class-AB PAs while maintaining the biasing voltage of a main PA of the two class-AB PAs constant.

In some embodiments, at least one of the plurality of circuit branches comprises an impedance inverter coupled to an output of the class-AB PA.

In some embodiments, the plurality of circuit branches are connected to the output via a matching network.

According to one aspect of this disclosure, there is provided a method for determining a phase-adjustment value for used in the above-described linear power-amplification module, the method comprising: introducing a series of phase-shift values to the plurality of circuit branches while fixing power proportionality and the biasing voltages of the class-AB PAs; for each of the series of phase-shift values, inputting signals of different powers to the linear power-amplification module and determining a set of intermodulation distortion (IMD) values and a set of power-added-efficiency (PAE) values for the phase-shift value, thereby obtaining a plurality of sets of IMD values and a plurality of sets of PAE values; identifying one or more phase-shift values whose corresponding IMD values within a target power output or power input range are greater than an IMD threshold; and for each of a plurality of power output or power input values within the target power output or power input range, selecting, from the identified one or more phase-shift values, a phase-shift value with greatest PAE value as the phase-adjustment value for the power output or power input value.

According to one aspect of this disclosure, there is provided a method for determining a plurality of power proportionality values of the class-AB PAs for used in the above-described linear power-amplification module, the method comprising: introducing a series of power-proportionality values of the class-AB PAs; for each of the series of power-proportionality values, inputting signals of different powers to the linear power-amplification module and determining a set of IMD values and a set of PAE values for the phase-shift value, thereby obtaining a plurality of sets of IMD values and a plurality of sets of PAE values; identifying one or more power-proportionality values whose corresponding IMD values within a target power output or power input range are greater than an IMD threshold; and for each of a plurality of power output or power input values within the target power output or power input range, selecting, from the identified one or more power-proportionality values, a power-proportionality value with greatest PAE value as the determined power-proportionality value for the power output or power input value.

According to one aspect of this disclosure, there is provided a method for determining one or more values of one or more parameters for used in the above-described linear power-amplification module, the method comprising: introducing a plurality of sets of parameter values of the one or more parameters to the linear power-amplification module; for each set of the parameter values, inputting signals of different powers to the linear power-amplification module and determining a set of IMD values and a set of PAE values for the set of parameter values, thereby obtaining a plurality of sets of IMD values and a plurality of sets of PAE values; identifying one or more sets of parameter values whose corresponding IMD values within a target power output or power input range are greater than an IMD threshold; and for each of a plurality of power output or power input values within the target power output or power input range, selecting, from the identified one or more set of parameter values, a set of parameter values with greatest PAE value as the determined power-proportionality value for the power output or power input value.

In some embodiments, the one or more parameters comprise at least one of phase-adjustment between the circuit branches, and power proportionality of the class-AB PAs.

According to one aspect of this disclosure, there is provided a non-transitory computer readable storage medium having stored thereon computer-executable instructions that, when executed by a computer, cause the computer to perform the method shown above.

The linear power-amplification module disclosed herein provides various benefits, such as:
both the main and peaking PAs are operated in their linear Class-AB regions, and thus there is no need for matching of peaking and compression response at final response;
the adaptive biasing of both main and peaking PAs improves the efficiency and linearity of the linear power-amplification module at the same time, and thus the main PA may be maintained at ideal load for required output power to ensure linearity and efficiency performance without dynamic load variation;
by using the simple LUT method to digitally control the attenuators, the gain amplifiers, and the driver amplifiers to reconfigure the input power-division ratio and phase shift, the system complexity is reduced due to analog linearization with simple LUT digital-control instead of using complex DSP and/or DPD and changing drain biasing as in prior art;
the linear power-amplification module disclosed herein is not frequency dependent and does not need complex high-speed DSP, DAC and DPD; and
the linear power-amplification module disclosed herein may be used in embodiments using phase array tapering for changing the relative output power with improved efficiency while maintaining required linearity.

### BRIEF DESCRIPTION OF THE DRAWINGS

For a more complete understanding of the disclosure, reference is made to the following description and accompanying drawings, in which:

FIG. 1 is a plot showing the input/output relationship of a linear power amplifier (PA);

FIG. 2 is a schematic diagram showing the structure of a conventional average-power tracking Doherty power amplifier (DPA);

FIG. 3 is a circuit diagram of a conventional average-power tracking DPA;

FIG. 4 is a plot showing the behavior of the average-power tracking DPA shown in FIG. 2;

FIG. 5 is a plot showing simulation results of the average-power tracking DPA shown in FIG. 2 with reduced power operation;

FIG. 6 is a schematic diagram showing a dual-input DPA transmitter architecture;

FIG. 7 is a plot showing the simulated power-added-efficiency (PAE) of the dual-input DPA shown in FIG. 6 with and without adaptive phase alignment;

FIG. 8 is a schematic diagram showing an analog linear power-amplification module, according to some embodiments of this disclosure;

FIG. 9 is a schematic diagram showing the detail of the linear power-amplification module shown in FIG. 8, according to some embodiments of this disclosure;

FIG. 10 is a plot showing the sample simulation results of the intermodulation distortion (IMD) and PAE of the linear power-amplification module shown in FIG. 9 vs. the output power thereof at different input-signal phase-shifts but with fixed input power-division ratio;

FIG. 11 is a plot showing the sample simulation results of the amplitude-to-phase (AM-PM) distortion of the linear power-amplification module shown in FIG. 9 vs. the output power thereof at different input-signal phase-shifts but with fixed input power-division ratio; and

FIG. 12 is a plot showing the sample simulation results of the IMD and PAE of the linear power-amplification module shown in FIG. 9 vs. the output power thereof with different input power-division ratios at a fixed phase shift.

### DETAILED DESCRIPTION

### A. Linear Power Amplifier

Conventional linear-mode power amplifiers (PAs) generally include Class-A, Class-B, and Class-AB PAs defined by the varying conduction angles. More specifically, Class-A PAs have a conduction angle of 360°, Class-B PAs have a conduction angle of 180°, and class-AB PAs have a conduction angle between 180° and 360°.

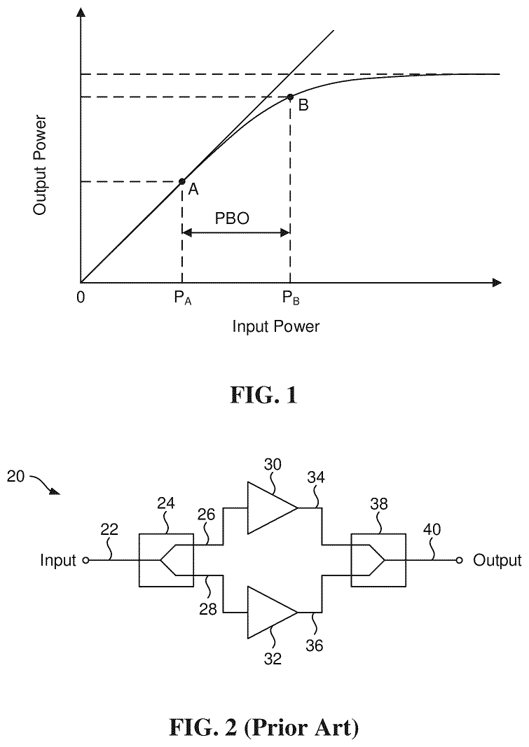

A linear-mode PA generally has a limited linear range. FIG. 1 shows the input/output power relationship of a linear-mode PA. As shown, the input/output power relationship is generally linear (that is, the output power is a linear amplification of the input power) between the origin and the P1dB point B (thereby defining an input linear range from zero (0) to PB), wherein the P1dB point is the point where the output power is one (1) decibel (dB) smaller than the otherwise linearly amplified power value. When the input power is greater than PB, the output is significantly distorted (that is, no longer a linear amplification of the input power) and eventually saturated to a maximum output power.

Signals having high peak-to-average power ratio (PAPR) such as the quadrature amplitude modulation (QAM) signals generally have maximum powers significantly greater than the average powers thereof. Thus, when using a PA to amplify a signal with high PAPR, the operation point A of the PA (corresponding to the average power of the signal) has to sufficiently “back off” from the saturation point S. In other words, the average power PA of the signal input to the PA has to be sufficiently smaller than PB (the upper bound of the PA's linear range) to ensure that the entire signal may be linearly amplified without significant distortion. The difference between PB and PA is denoted power back-off (PBO). A high PBO may greatly reduce the efficiency at the low output powers for conventional linear-mode PAs, thereby causing a low PBO efficiency problem.

The Doherty power amplifier (DPA) provides a solution to the low PBO efficiency problem. As shown in FIG. 2, the conventional DPA 20 comprises a splitter or hybrid coupler 24 to split the input signal 22 into two signals 26 and 28 with a 90° phase shift therebetween. The signal 26 passes through a main PA 30 (also denoted a “carrier PA”) which is a Class-A or Class-AB PA operating on the entire input signal 26. The signal 28 passes through a peak PA 32 (also denoted a “peaking PA”) which is a Class-C PA only operating on a peak-power portion of the input signal 28 (that is, the peak PA 32 is off on a major portion of the input signal 28 and is turned on only when the power of the input signal 28 is greater than a threshold). By carefully choosing the parameters of the PAs 30 and 32, the peak PA 32 may be on and operate when the main PA 30 starts to saturate. The outputs 34 and 36 of the PAs 30 and 32 are combined (with an inverse 90° phase shift) by a combiner 38 to use the output 36 of the peak PA 32 to compensate for the peak distortion/saturation of the output 34 of the main PA 30. The combined output signal 40 is then a substantially linearly amplified version of the input signal 22.

The conventional DPA 20 suffers from potential linearity issue of final response (that is, the output signal 40). First, at low input power level, only the main PA 30 is on and operates at peak or near peak power-added-efficiency (PAE) at the PBO. Second, at high input power levels, the peak PA 32 begins to conduct and rely on active load modulation to change the load seen at the main PA 30. Any additional un-wanted non-linearity caused by this load modulation would directly affect the final response.

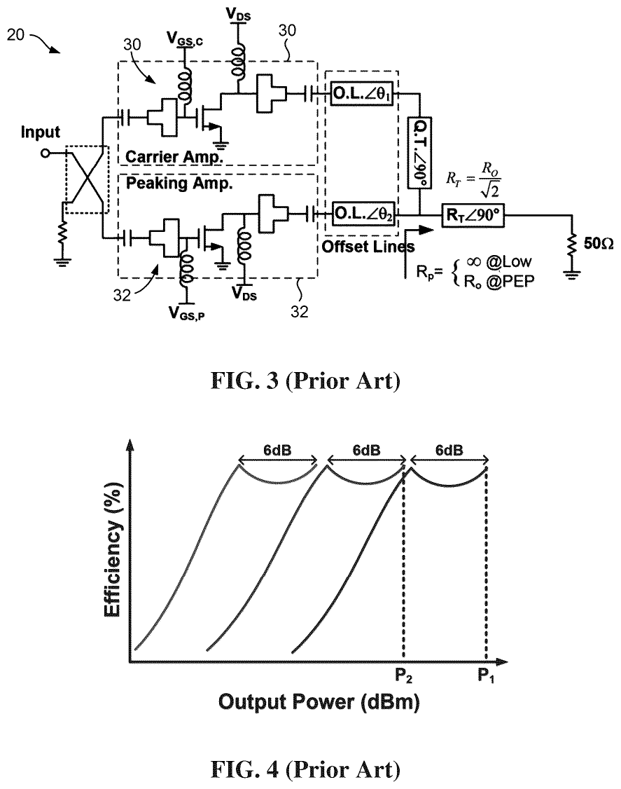

FIG. 3 is a circuit diagram of an average-power tracking DPA 20 described in Reference [1], wherein the carrier PA 30 is a Class-A or Class-AB PA, and the peaking PA 32 is a Class-C PA. The average-power tracking DPA 20 provides further extended efficiency range (greater than 6 dB at PBO) by changing the drain-bias voltage V_{DS} and the gate-bias voltages V_{GS,C} and V_{GS,P} of the carrier and the peak PAS 30 and 32.

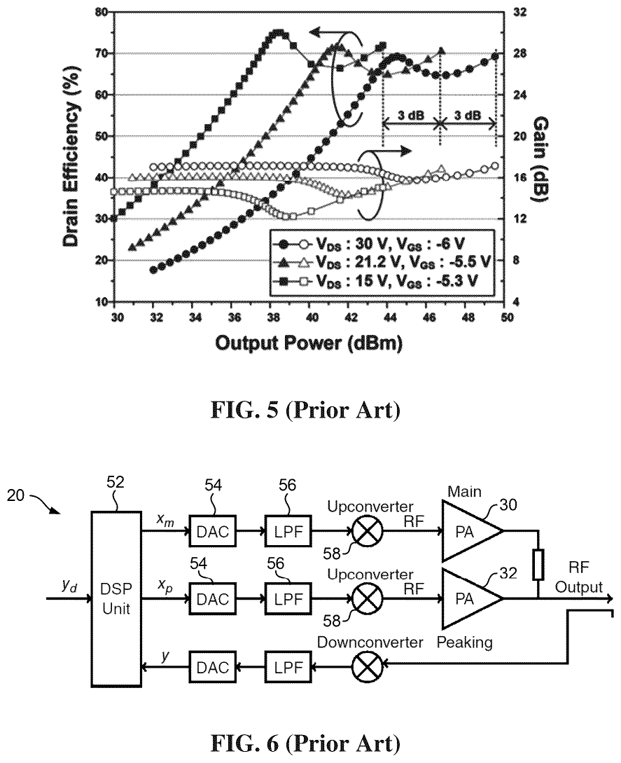

FIG. 4 is a plot showing the behavior of the average-power tracking DPA 20 shown in FIG. 3. When the peak output power is decreased from P₁ to P₂, the average-power tracking DPA 20 needs to reduce the drain-bias and gate-bias voltages V_{DS}, V_{GS,C}, and V_{GS,P} to achieve high efficiency at a low peak power P2. Sample simulation results of the average-power tracking DPA 20 are shown in FIG. 5. As those skilled in the art will understand, in the average-power tracking DPA 20 shown in FIG. 3, changing the drain-bias voltage requires digital trimming of the internal or external power supply regulator, which may further increase the system complexity and power consumption, and the power efficiency improvement thereof may be degraded.

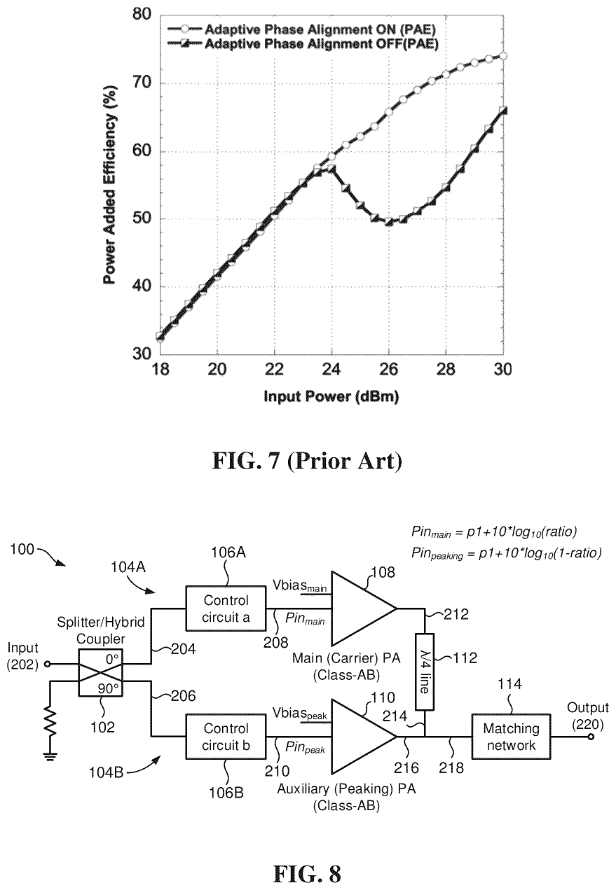

FIG. 6 is a schematic diagram showing a DPA 20 proposed in Reference [2] and described in Reference [3], wherein the carrier PA 30 is a Class-A or Class-AB PA, and the peaking PA 32 is a Class-C PA. The DPA 20 shown in FIG. 6 improves the PAE with the adaptive phase alignment. As shown, the dual input signals Y_{d} (comprising the In-phase and Quadrature (I/Q) components and upconverters 58) are processed by the digital signal processing (DSP) unit 52 and the digital-to-analog convertors (DACs) 54 (also passing the lowpass filters (LPFs) 56) to adaptively align the phases of the carrier and peaking paths for all power levels when the peaking PA 32 is on in order to optimize the overall efficiency of the DPA 20. FIG. 7 is a plot showing the improvement of the PAE.

However, the dual inputs with DSP technique only take care of the phase alignment of the main and peaking PAs 30 and 32 to prevent efficiency degradation.

Digital predistortion (DPD) can potentially solves the linearity problem with the DPAs. For example, the DPAs shown in FIGS. 3 and 6 may use advanced DPD algorithms to improve the linearity performance thereof. However, DPD may not be preferable due to low output power levels in millimeter-wave (mmWave) applications and the system complexity thereof (because of high signal bandwidth and large number of PAs requiring linearization).

High efficiency and high linearity PAs are always desirable in wireless communication systems, especially in mmWave, 5G, beyond-the-fifth-generation (B5G), 6G phase arrays with the complex modulation methods for high throughputs, wherein the systems require PAs to operate with high PAPR and at the PBO from the peak power.

In the following, a cost-effective analog linear PA is disclosed, which may be suitable for use in wireless communication systems such as 5G and 6G systems with improved efficiency and linearity of the PA at the PBO. The linear PA disclosed here may be considered an improved DPA for providing a cost-effective solution to optimize the power efficiency and linearity at the PBO region to satisfy the system requirement of phase arrays with high-order QAMs. The PBO efficiency and linearity of the DPA are optimized at the same time in the analog domain without using DPD linearization, thereby effectively reducing the overall system complexity.

Turning now to FIG. 8, an analog linear power-amplification module according to some embodiments of this disclosure is shown and is generally identified using reference numeral 100. In various embodiments, the linear power-amplification module 100 may be used in any suitable wireless communication systems such as in the RF, mmWave, 5G, beyond the fifth generation (B5G), 6G transceivers thereof with complex modulation methods for high throughputs and requiring high efficiency and high linearity PAs to operate with high PAPR at the PBO from the peak power. The linear power-amplification module 100 allows a range of operating output powers with improved efficiency but maintain reasonable linearity.

As shown, the linear power-amplification module 100 has a modified DPA structure and comprises a splitter or hybrid coupler 104 to split an input signal 202 into a first split signal 204 and a second split signal 206. In these embodiments, the first and second signals 204 and 206 are of substantially equal amplitudes and with a phase shift such as a 90° phase-shift therebetween.

The first signal 204 goes through a first branch or path 104A, passing a first control circuit 106A and then being amplified by a main PA 108 which in these embodiments is a Class-AB PA. The amplified first signal 212 the passes an impedance inverter 112 such as a quarter-wave (\/4, where) is the wavelength of the first signal 204) transmission line, which modulates the load seen at the output of the main PA 108 and applies a −90° phase shift to the amplified first signal 212 to counter the phase shift introduced by the splitter 104. An amplified and phase-corrected first signal 214 is then output from the impedance inverter 112. In the simplest embodiment, the control circuit 106A may only comprise gain stages with no level adjustment or bias control. The control circuit 106A may also contain a phase adjustment.

The second signal 206 goes through a second branch or path 104B, passing a second control circuit 106B and then being amplified by a peaking PA 110 which in these embodiments is a Class-AB PA. The amplified second signal 216 and the amplified and phase-corrected first signal 214 (which are in-phase) are combined to form a combined signal 218 which is a linear amplification of the input signal 202. Those skilled in the art will recognized that signal 216 when combined with signal 212 may vary the impedance seen by the main amplifier 108 in an inverse relationship to the relative levels of signal 216 and 212. In these embodiments, the combined signal 218 passes a matching network 114 for output. As those skilled in the art will appreciate, the matching network 114 is used to transform the load to a desired impedance at the output connection of the peaking and main PAs 108 and 110 in order to optimize the overall efficiency and linearity. Those skilled in the art will also appreciate that other DPA topologies such as those employing for example series- or parallel-coupled transformers or other means of splitting signal 202 into signals 204/206 and combining signals 212/216 into signal 218 may be improved in a similar manner.

In these embodiments, the control circuits 106A and/or 106B use an adaptive control method such as a calibration-based control method or a look-up table (LUT) based control method (described in more detail later) to adaptively control the input powers Pinₘₐᵢₙ and Pin_{peaking} of the main PA 108 and the peaking PA 110, respectively, and the operation points thereof if the output characteristics are repeatable and depending on the required/expected target output power.

For example, in some embodiments where non-constant-envelope signals (that is, the signals whose envelope (that is, the peaks thereof) are non-constant) such as QAM signals are used as the input signal 202, the output signal 220 is a linearly amplified version of the input QAM signals. In these embodiments, the input and output powers of the linear power-amplification module 100, and Pinₘₐᵢₙ and Pin_{peaking} of the main PA 108 and the peaking PA 110 refer to the respective powers in accordance with a non-constant-envelope signal input to the linear power-amplification module 100.

The control circuits 106A and/or 106B may use the adaptive control method to adjust Pinₘₐᵢₙ and Pin_{peaking} of the main PA 108 and the peaking PA 110 and the operation points thereof based on the target output power (or equivalently, the input power, for example, the power of each input QAM signal) to achieve linear amplification of the input signal 202 with improved PAE, wherein the amplification linearity may be measured by the intermodulation distortion (IMD) of the output signal 220. For example, the output signal 220 may be represented as:

$$y ( t ) = α x ( t ) + d ( t ) \qquad ( 1 )$$

where y(t) is the output signal 220, x(t) is the input signal 202, α is the amplification factor, and d(t) is the distortion introduced by the nonlinearity of the linear power-amplification module 100. Then, the IMD may be defined as:

$$IMD = {P}_{x} - {P}_{d} \qquad ( 2 )$$

where Pₓ and P_{d} are the power in dB or decibel-milliwatts (dBm) of x(t) and d(t).

For example, in some embodiments, the control circuits 106A and/or 106B may use the adaptive control method to adjust a power-division ratio r (1≥r≥0) for adjusting Pinₘₐᵢₙ and Pin_{peaking} for varying the load on main PA 108 as follows:

$${Pin}_{m a i n} = P 1 + 10 {log}_{10} ( r ) \qquad ( 3 )$$

$${Pin}_{p e a k i n g} = P 1 + 10 ( 1 - r ) \qquad ( 4 )$$

where P1 is a power proportional to the input power (that is, the power of an input QAM signal as the input signal 220) which corresponds to the target output power (that is, the target power of the output signal 220). In these embodiments, the power-division ratio 1≥r≥0.5.

With the adjustment of Pinₘₐᵢₙ and Pin_{peaking} of the main PA 108 and the peaking PA 110, the adaptive control method may also accordingly adjust the bias voltage Vbiasₘₐᵢₙ of the main PA 108 and the bias voltage Vbiasₚₑₐₖ) of the peaking PA 110 to ensure that they operate within their Class-AB linear regions. In some embodiments, the bias voltages Vbiasₘₐᵢₙ and Vbiasₚₑₐₖ of the main and peaking PAs 108 and 110 may be adjusted, for example, by adjusting their bias currents as follows:

$${Iref}_{m a i n} = {I}_{m a i n} - ( m - 0.5 ) \times {I}_{s u b} \qquad ( 5 )$$

$${Iref}_{p e a k i n g} = {Iref}_{m a i n} * ( 1 - ( m - 0 \text{.5} ) / 0.5 ) \qquad ( 6 )$$

where Irefₘₐᵢₙ is the reference bias current of the main PA 108 (that is, the bias current of the main PA 108 to be adjusted thereto), Iref_{peaking} is the reference bias current of the peaking PA 110, Iₘₐᵢₙ is the input current of the main PA 108, I_{sub} is a predefined current value, and m is the current mirror ratio. In these embodiments, Iₘₐᵢₙ and I_{sub} are constant currents depending on the required or expected target output power range of the linear power-amplification module 100 (equivalent to the input power range), and the current mirror ratio m has the same value as the power-division ratio r (that is, m=r).

Based on Equations (5) and (6), the adaptive control method may use various ways to adjust or control the biasing voltage Vbiasₘₐᵢₙ and Vbiasₚₑₐₖ of the main and peaking PAS 108 and 110. For example, in one embodiment, the adaptive control method may set the reference bias current Irefₘₐᵢₙ (and thus the biasing voltage Vbiasₘₐᵢₙ) of the main PA 108 and thus the biasing voltage Vbiasₘₐᵢₙ thereof to a constant level (except possible variation thereof for typical process and temperature compensation, which is out of the scope of this disclosure and is omitted), and adjusts or controls the reference bias current Iref_{peaking} of the peaking PA 110 to set the Vbiasₚₑₐₖ. In another embodiment, the adaptive control method may adjust or control both reference bias currents Irefₘₐᵢₙ and Iref_{peaking} to set the Vbiasₘₐᵢₙ and Vbiasₚₑₐₖ.

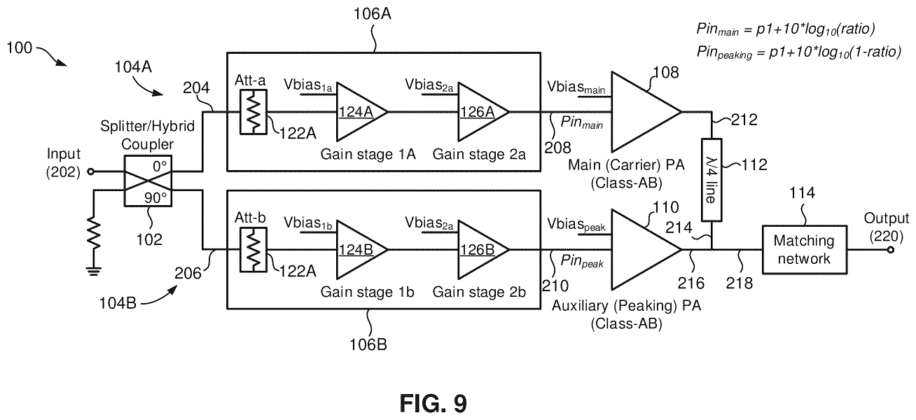

FIG. 9 is a schematic diagram showing the detail of the linear power-amplification module 100 according to some embodiments of this disclosure. As shown, the first control circuit 106A comprises a high-resolution attenuator (Att-a) 122A such as a digital-control attenuator for receiving the first signal 204, a gain amplifier (Gain stage 1a) 124A connecting to the attenuator 122A, and a driver amplifier (Gain stage 2a) 126A connecting the gain amplifier 124A to the main PA 108.

Similarly, the second control circuit 106B comprises a high-resolution attenuator (Att-b) 122B such as a digital-control attenuator for receiving the second signal 206, a gain amplifier (Gain stage 1b) 124B connecting to the attenuator 122B, and a driver amplifier (Gain stage 2b) 126B connecting the gain amplifier 124B to the peaking PA 110. In these embodiments, the corresponding components 122A and 122B, 124A and 124B, and 126A and 126B of the main path 106A and the peaking path 106B are substantially identical. For ease of description, the gain amplifiers 124A and 124B and the driver amplifiers 126A and 126B may be collectively denoted “adjustment amplifiers”.

In these embodiments, the adaptive control method adaptively controls the attenuations of the attenuators 122A and 122B, and the biasing voltages Vbias₁ₐ of the gain amplifier 124A, Vbias_{1b} of the gain amplifier 124B, Vbias₂ₐ of the driver amplifier 126A, and Vbias_{2b} of the driver amplifier 124B to adjust the power-division ratio r as described above. The adaptive control method also controls the reference bias currents Irefₘₐᵢₙ and Iref_{peaking} to set the Vbiasₘₐᵢₙ and Vbiasₚₑₐₖ so as to operate the main and peaking PAS 108 and 110 within their linear range.

In some embodiments, the phase shift introduced by the impedance inverter 112 may not fully match (that is, fully compensate for) the phase shift introduced by the splitter 102. In these embodiments, the adaptive control method may also adaptively control the control circuits 106A and/or 106B for adjusting the phase shift between the input signals 208 and 210 of main and peaking amplifiers 108 and 110 for aligning the amplified first and second signals 214 and 216 to be in phase.

For example, in the example shown in FIG. 9, the attenuators 122A and 122B generally have relatively constant phase shift within its attenuation range. To achieve a required input power-division ratio with suitable phase shift in the range between Pinₘₐᵢₙ and Pin_{peaking}, each of the attenuators 122A and 122B may be set to a desired attenuation setting (determined by a calibration procedure; described in more detail below) and the bias voltages of the gain amplifiers 124A and 124B and driver amplifiers 126A and 126B may be also set to a suitable value (determined by the calibration procedure; described in more detail below) to satisfy the relationship in Equations (3) and (4). The phase shift between the two branches 104A and 104B may then be fine-tuned while setting the constant power relative levels between Pinₘₐᵢₙ and Pin_{peaking} (for example, by setting the power-division ratio r) to optimize the efficiency and linearity of the linear power-amplification module 100. For phase array tapering, the output power of each path driving an element or group of elements may not be constant. The relative output power of each path may be set through the same mechanism as above without adjusting the power supply voltage while the efficiency and linearity of the power-amplification module 100 is optimized at the same time.

In some embodiments, a calibration procedure may be used for determining the control parameters used by the adaptive control method.

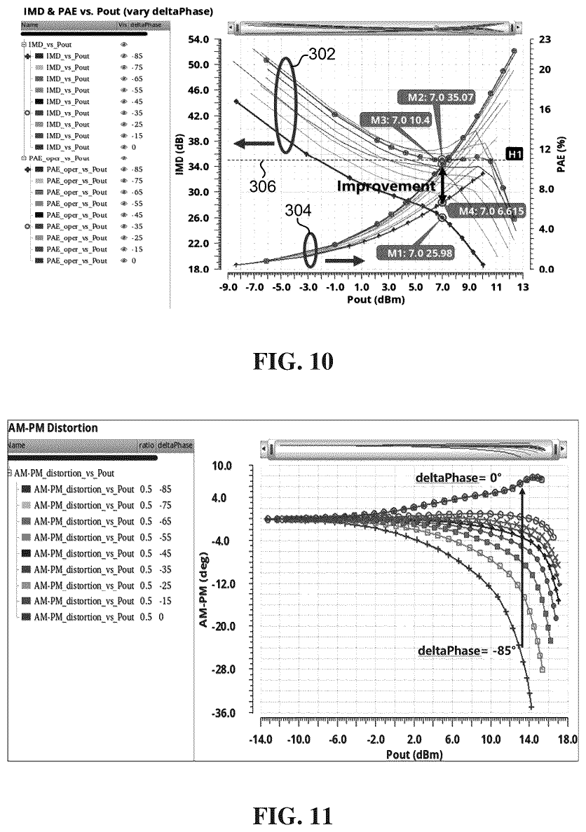

The calibration procedure first determines a phase adjustment for compensating the possibly mismatched phase shifts introduced by the splitter 102 and the impedance inverter 112. With reference to FIG. 10, the power-division ratio r (that is, the power proportionality of the input powers of the main and peaking PAs 108 and 110) and the biasing voltages Vbiasₘₐᵢₙ and Vbiasₚₑₐₖ of the main and peaking PAs 108 and 110 are set to fixed values, and the control circuits 106A and/or 106B are tuned to introduce a series of phase-adjustment values (such as from 0° to 85° in the example shown in FIG. 10) between the input signals 208 and 210 of main and peaking amplifiers 108 and 110 (thus introducing the phase-adjustment values between the amplified signals 212 and 216). For each phase-adjustment value, signals 102 of different powers are input to the linear power-amplification module 100. The IMD and PAE are calculated based on the output signal 220. A plurality of IMD curves 302 (each IMD curve having a plurality of IMD values with each IMD value corresponding to a target output power or a target input power) and a plurality of PAE curves 304 (each PAE curve having a plurality of PAE values with each PAE value corresponding to a target output power or a target input power) are then obtained with each IMD curve and each PAE curve corresponding to a specific phase-adjustment value, and each IMD curve corresponding to a PAE curve. As can be seen, the IMD curves 302 generally decrease with the increase of the output power Pout, and the PAE curves 304 generally increase with the increase of Pout.

The requirement of linearity of the linear power-amplification module 100 is satisfied when the IMD is greater than an IMD threshold, where the value of the IMD threshold depends on the application or use scenario. In the example shown in FIG. 10, the requirement of linearity of the linear power-amplification module 100 is satisfied when the IMD is greater than an IMD threshold of 35 dB (represented by the dashed line 306). Within a desired or required target Pout range, for example between 4.5 dBm and 12 dBm, some phase-adjustment values are eliminated because their IMD values are smaller than the IMD threshold. The PAE curves of the remaining phase-adjustment values are used to select a phase-adjustment value with the largest PAE value among the remaining PAE curves for each Pout value within the target Pout range. For example, for Pout=7 dBm, the phase-adjustment value of −35° gives rise to an IMD greater than 35 dBm and the largest PAE value, which improves the IMD from 26 dB to 35 dB and improves the PAE from 6.6% to 10.4% (about 36.5% power reduction at the same output power level).

FIG. 11 is a plot showing the simulation results with fixed Pin_{peaking} and Pinₘₐᵢₙ power-division ratio r and biasing points for the main and peaking PAs 108 and 110 but with different phase alignments (phase shift) between the input signals of the main and peaking PAs 108 and 110. As can be seen, the amplitude-to-phase (AM-PM) distortion is optimized while IMD is improved.

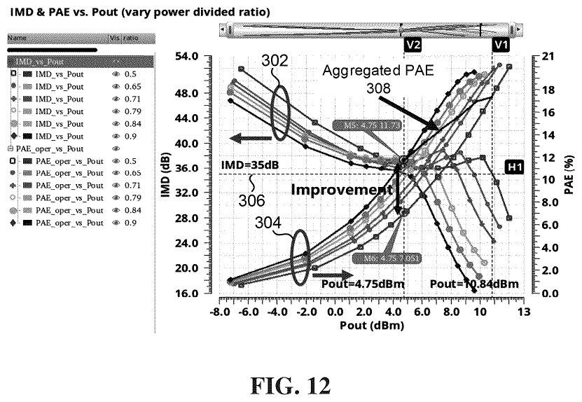

After the phase-adjustment values are determined, the calibration procedure then determines the values of the power-division ratio r (that is, the power proportionality of input powers of the main and peaking PAS 108 and 110) for different output powers Pout (or for different input powers). As shown in FIG. 12, the control circuits 106A and/or 106B introduce the determined phase-adjustment value, and are tuned to set a series of values of the power-division ratio r. For each power-division ratio r, signals 102 of different powers are input to the linear power-amplification module 100. The IMD and PAE are calculated based on the output signal 220. A plurality of IMD curves 302 and a plurality of PAE curves 304 are then obtained with each IMD curve and each PAE curve corresponding to a specific phase adjustment-value, and each IMD curve corresponding to a PAE curve. As can be seen, the IMD curves 302 generally decrease with the increase of the output power Pout, and the PAE curves 304 generally increase with the increase of Pout.

The requirement of linearity of the linear power-amplification module 100 is satisfied when the IMD is greater than an IMD threshold, where the value of the IMD threshold depends on the application or use scenario. In the example shown in FIG. 11, the requirement of linearity of the linear power-amplification module 100 is satisfied when the IMD is greater than an IMD threshold of 35 dB (represented by the dashed line 306). Within a target Pout range, for example between 4.5 dBm and 12 dBm, some r values are eliminated because their IMD values are smaller than the IMD threshold. For each Pout value within the target Pout range, the PAE curves of the remaining r values are used to select an r value with the largest PAE value among the remaining PAE curves, giving rise to an aggregated PAE curve 308. For example, for Pout=4.75 dBm, r=0.9 gives rise to an IMD greater than 35 dBm and the largest PAE value which improves the PAE from 7.1% to 11.7% (about 4.7% PAE improvement at 6 dB reduction from peak operating power, which is about 40% power reduction at the same output power level).

The aggregated PAE curve 308 may be used by the adaptive control method for adaptively adjusting the power-division ratio during the operation of the linear power-amplification module 100. For example, in some embodiments, a LUT may be obtained from the aggregated PAE curve 308 with a lookup column of different Pout values (or corresponding input power values) and a column of the corresponding r values. The adaptive control method may use the LUT to select a suitable r value based on the required output power (or based on the input power).

Those skilled in the art will appreciate that, in these embodiments, the adaptive control method uses the biasing to adjust the IMD and PAE curve. Consequently, the PBO for each curve is substantially the same. However, the P1dB is shifted to maintain the linearity (IMD) and efficiency (PAE).

In above embodiments, the calibration procedure separately determines the phase-adjustment values and the values of the power-division ratio r (that is, the power proportionality between the input powers of the main PA 108 and the peaking PA 110).

When determining the phase-adjustment values, the calibration procedure introduces a series of phase-adjustment values between the circuit branches 104A and 104B while fixing the power proportionality and the biasing voltages of the main PA 108 and the peaking PA 110. For each of the series of phase-adjustment values, the calibration procedure inputs signals of different powers to the linear power-amplification module 100 and determines a set of IMD values and a set of PAE values for the phase-adjustment value, thereby obtaining a plurality of sets of IMD values (wherein each IMD value corresponds to a target output power or a target input power of the linear power-amplification module 100; and each set of IMD values may be visually represented by an IMD curve as shown in FIG. 10) and a plurality of sets of PAE values (wherein each PAE value corresponds to a target output power or a target input power of the linear power-amplification module 100; and each set of PAE values may be visually represented by a PAE curve as shown in FIG. 10).

The calibration procedure identifies one or more phase-adjustment values whose corresponding IMD values within a target power output or power input range are greater than an IMD threshold. Then, for each of a plurality of power output or power input values within the target power output or power input range, the calibration procedure selects, from the identified one or more phase-adjustment values that correspond to the power output or power input value, a phase-adjustment value with the greatest PAE value as the phase-adjustment value for that power output or power input value.

Similarly, when determining the values of the power-division ratio r (that is, the power-proportionality values), the calibration procedure introduces a series of power-proportionality values for the main PA 108 and the peaking PA 110. For each of the series of power-proportionality values, the calibration procedure inputs signals of different powers to the linear power-amplification module 100 and determines a set of IMD values and a set of PAE values for the power-proportionality value, thereby obtaining a plurality of sets of IMD values (wherein each IMD value corresponds to a target output power or a target input power of the linear power-amplification module 100; and each set of IMD values may be visually represented by an IMD curve as shown in FIG. 12 and a plurality of sets of PAE values (wherein each PAE value corresponds to a target output power or a target input power of the linear power-amplification module 100; and each set of PAE values may be visually represented by a PAE curve as shown in FIG. 10).

The calibration procedure identifies one or more power-proportionality values whose corresponding IMD values within a target power output or power input range are greater than an IMD threshold. Then, for each of a plurality of power output or power input values within the target power output or power input range, the calibration procedure selects, from the identified one or more power-proportionality values that correspond to the power output or power input value, a power-proportionality value with the greatest PAE value as the determined power-proportionality value for that power output or power input value.

In some embodiments, the calibration procedure may determine the phase-adjustment values and the power-proportionality values together.

In these embodiments, the calibration procedure introduces a plurality of combinations of the phase-adjustment values and the power-proportionality values to the linear power-amplification module 100. For each combination of the phase-adjustment value and the power-proportionality value, the calibration procedure inputs signals of different powers to the linear power-amplification module 100 and determines a set of IMD values and a set of PAE values for the power-proportionality value, thereby obtaining a plurality of sets of IMD values (wherein each IMD value corresponds to a target output power or a target input power of the linear power-amplification module 100; and each set of IMD values may be visually represented by an IMD curve as shown in FIG. 12 and a plurality of sets of PAE values (wherein each PAE value corresponds to a target output power or a target input power of the linear power-amplification module 100; and each set of PAE values may be visually represented by a PAE curve as shown in FIG. 10).

The calibration procedure identifies one or more combinations of the phase-adjustment values and the power-proportionality values whose corresponding IMD values within a target power output or power input range are greater than an IMD threshold. Then, for each of a plurality of power output or power input values within the target power output or power input range, the calibration procedure selects, from the identified one or more combinations of the phase-adjustment values and the power-proportionality values that correspond to the power output or power input value, a combination of the phase-adjustment value and the power-proportionality value with the greatest PAE value as the determined combination of the phase-adjustment value and the power-proportionality value for that power output or power input value.

In some embodiments, the calibration procedure does not determine the phase-adjustment values (thus, assume the phase shifts introduced by the splitter 102 and the impedance inverter 112 match, and any phase-shift mismatch may introduce IMD).

In above embodiments, the splitter 104 performs the 90° signal split. In some other embodiments, other suitable component or circuit may be used for the 90° signal split. Moreover, in various embodiments, the attenuators 122A and 122B may be any suitable attenuators such as analog-control attenuators, digital variable gain amplifiers (VGAs), analog VGAs, and/or the like to operate the main and peaking PAS 108 and 110 in their Class-AB region but with changing of the P1dB operating point.

As those skilled in the art will appreciate, the phase shift introduced by the splitter 102 is for compensating for the phase shift caused by the impedance transformer 112. In some embodiments wherein the impedance transformer 112 causes a phase shift θ (not necessarily 90° and may be) 0° between the first and second split signals 204 and 206, the splitter 102 may introduce an inverse phase shift −θ. In some embodiments, the splitter 102 may introduce the inverse phase shift −θ. Rather, a separate phase shifter may be included in the first control circuit 106A and/or second control circuit 106B to compensate for the phase shift caused by the impedance transformer 112.

In some embodiments, the first and/or second control circuits 106A and/or 106B may not comprise any attenuators.

In some embodiments, the first control circuit 106A may comprise a plurality of gain amplifiers 124A, and the first control circuit 106A may comprise a plurality of gain amplifiers 124B depending on the overall gain requirement of the linear power-amplification module 100. Each of the gain amplifiers 124A and 124B may comprise its dedicated digital control for its bias voltage to facilitate the optimization of the power efficiency and linearity at the same time.

In some embodiments, the gain amplifier 124A and the driver amplifier 126A may be combined into a single amplifier. Similarly, the gain amplifier 124B and the driver amplifier 126B may be combined into a single amplifier.

In some embodiments, the linear power-amplification module 100 may not comprise any gain and/or driver amplifiers 124A, 124B, 126A, and/or 126B, and the adjustment of the power-division ratio is conducted by the attenuators 122A and 122B. However, the effectiveness of the linear power-amplification module 100 in these embodiments may be reduced.

In some embodiments wherein phase array tapering is used, the output power of each phase-array channel may not be constant. In these embodiments, the linear power-amplification module 100 may be used with changeable relative output power. That is, by controlling the bias voltages of the amplifiers 124A, 124B, 126A, 126B, 108, and 110, the output power may be adjusted without adjusting the input power of the linear power-amplification module 100 and thus without adjusting the power supply voltage for each channel of the phase array.

In above embodiments, the adaptive control method adjusts the bias voltage Vbiasₘₐᵢₙ of the main PA 108, in some other embodiments, the adaptive control method may not adjust the bias voltage Vbiasₘₐᵢₙ of the main PA 108.

In above embodiments, the splitter 102 splits the input signal to the first and second signals with substantially equal powers. In some embodiments, the first and second signals may have different powers.

In some of above embodiments, the adaptive control method is configured for adjusting the power-division ratio r in accordance with Equations (3) and (4). Those skilled in the art will appreciate that adjusting the power-division ratio r is equivalent to adjusting the power-division percentages of the input powers Pinₘₐᵢₙ and Pin_{peaking} of the main and peaking PAs 108 and 110, that is:

$${Pin}_{m a i n} = P 1 + 10 {log}_{10} ( {x}_{m a i n} ) \qquad ( 7 )$$

$${Pin}_{p e a k i n g} = P 1 + 10 ( {x}_{p e a k i n g} ) \qquad ( 8 )$$

where xₘₐᵢₙ and x_{peaking} are the power-division percentages of the input powers Pinₘₐᵢₙ and Pin_{peaking}, respectively, 1>xₘₐᵢₙ>0, 1>x_{peaking}>0, and xₘₐᵢₙ+x_{peaking}=1. In some embodiments, the power-division ratio 1>xₘₐᵢₙ≥0.5.

In above embodiments, the linear power-amplification module 100 comprises two branches 104A and 104B. In some embodiments, the linear power-amplification module 100 may comprise more than two branches. One or more splitters may be used to provide split signals to the branches. Moreover, the adaptive control method is configured for adjusting the power-division percentages of the input powers of the PAs of the than two branches in accordance with:

$${Pin}_{i} = P 1 + 10 {log}_{10} ( {x}_{i} ) \qquad ( 9 )$$

where i=1, 2, . . . . N is the index of the PAs (where N is the total number of the PAs), Pinᵢ is the input power of the i-th PA, xᵢ is the power-division percentage of the input power of the i-th PA, 1≥xᵢ≥0, and Σᵢ₌₁^{N}xᵢ.

While in above embodiments, each branch comprises a control circuit, in some embodiments, some branches may not comprise the control circuits.

In some embodiments, the linear power-amplification module 100 may not comprise any matching network 114.

The linear power-amplification module 100 disclosed herein provides various benefits, such as:
both the main and peaking PAS 108 and 110 are operated in their linear Class-AB regions, and thus there is no need for matching of peaking and compression response at final response;
the adaptive biasing of both main and peaking PAS 108 and 110 improves the efficiency and linearity of the linear power-amplification module 100 at the same time, and thus the main PA 108 may be maintained at ideal load for required output power to ensure linearity and efficiency performance without dynamic load variation;
by using the simple LUT method to digitally control the attenuators 122A and 122B, the gain amplifiers 124A and 124B, and the driver amplifiers 126A and 126B to reconfigure the input power-division ratio and phase shift, the system complexity is reduced due to analog linearization with simple LUT digital-control instead of using complex DSP and/or DPD and changing drain biasing as in prior art;
the linear power-amplification module 100 disclosed herein is not frequency dependent and does not need complex high-speed DSP, DAC and DPD; and
the linear power-amplification module 100 disclosed herein may be used in embodiments using phase array tapering for changing the relative output power with improved efficiency while maintaining required linearity.

### B. Acronym Key

Digital Predistortion: DPD
Digital Signal Processing: DSP
Doherty Power Amplifier: DPA
Intermodulation Distortion: IMD
“In-phase” and “Quadrature”: I/Q
Look-Up Table: LUT
Millimeter Wave: mmWave
Peak-to-Average Power Ratio: PAPR
Power Added Efficiency: PAE
Power Amplifier: PA
Power Back-Off: PBO
Quadrature Amplitude Modulation: QAM
Variable Gain Amplifier: VGA

### C. References

[1] Y. Park, J. Lee, S. Kim, D. Minn and B. Kim, “Analysis of Average Power Tracking Doherty Power Amplifier,” in IEEE Microwave and Wireless Components Letters, vol. 25, no. 7, pp. 481-483, July 2015, doi: 10.1109/LMWC.2015.2429071.
[2] R. Darraji, “A Dual-Input Digitally Driven Doherty Amplifier Architecture for Performance Enhancement of Doherty Transmitters,” in IEEE Transactions on Microwave Theory and Techniques, 2011.
[3] R. Pengelly, “Doherty's Legacy: A History of the Doherty Power Amplifier from 1936 to the Present Day,” in IEEE Microwave Magazine, 2016.

Although embodiments have been described above with reference to the accompanying drawings, those of skill in the art will appreciate that variations and modifications may be made without departing from the scope thereof as defined by the appended claims.

1. A linear power-amplification circuit, comprising:
a splitter for splitting an input signal into a plurality split signals;
a plurality of circuit branches connected to the splitter, each circuit branch of the plurality of circuit branches for receiving a respective split signal of a plurality of split signals; and
an output connected to the plurality of circuit branches for combining outputs of the plurality of circuit branches and outputting an output signal;
wherein each circuit branch of the plurality of circuit branches comprises a respective class-AB power-amplifier (PA) operable under a biasing voltage; and
wherein one or more circuit branches of the plurality of circuit branches each comprise a respective control circuit connected to an input of the respective class-AB PA.

2. The linear power-amplification circuit of claim 1, wherein each circuit branch of the plurality of circuit branches comprises the respective control circuit connected to the input of the respective class-AB PA.

3. The linear power-amplification circuit of claim 1, wherein one or more control circuits of the one or more circuit branches are configured for adjusting input powers of respective class-AB PAS.

4. The linear power-amplification circuit of claim 3, wherein the one or more control circuits of the one or more circuit branches are configured for adjusting the input powers of the respective class-AB PAs by adjusting power-division percentages of the input powers of the respective class-AB PAs in accordance with
$${Pin}_{i} = P 1 + 10 {log}_{10} ( {x}_{i} )$$
wherein P1 is a power proportional to a power of the input signal, i=1, 2, . . . . N and is an index of the respective class-AB PAs, N is a total number of the respective class-AB PAS, Pinᵢ is an input power of an i-th class-AB PA, xᵢ is a power-division percentage of the input power of the i-th class-AB PA, 1≥xᵢ≥0, and Σᵢ₌₁^{N}xᵢ=1.

5. The linear power-amplification circuit of claim 1, wherein one or more control circuits of the one or more circuit branches are configured for adjusting the biasing voltage of at least one class-AB PA of respective class-AB PAs.

6. The linear power-amplification circuit of claim 5, wherein the one or more control circuits of the one or more circuit branches are configured for adjusting the biasing voltage of the at least one class-AB PA of the respective class-AB PAs by adjusting biasing current of the at least one class-AB PA.

7. The linear power-amplification circuit of claim 1, wherein one or more control circuits of the one or more circuit branches are configured for applying phase adjustment between input signals of respective class-AB PAs of the one or more circuit branches.

8. The linear power-amplification circuit of claim 1, wherein at least one control circuit of one or more control circuits of the one or more circuit branches comprises at least one of an attenuator or one or more adjustment amplifiers.

9. The linear power-amplification circuit of claim 8, wherein the one or more control circuits of the one or more circuit branches are configured for adjusting input powers of respective class-AB PAs by adjusting at least one of an attenuation of the attenuator or biasing voltage of each of the one or more adjustment amplifiers.

10. The linear power-amplification circuit of claim 8, wherein the one or more control circuits of the one or more circuit branches are configured for adjusting a phase shift between the input signals of respective class-AB PAs of the one or more circuit branches by adjusting biasing voltage of at least one of the one or more adjustment amplifiers.

11. The linear power-amplification circuit of claim 1, further comprising:
two circuit branches each comprising the respective control circuit connected to an input of the respective class-AB PA.

12. The linear power-amplification circuit of claim 11, wherein one or more control circuits of the one or more circuit branches are configured for adjusting input powers of class-AB PAs with a parameter r in accordance with
$${Pin}_{m a i n} = P 1 + 10 {log}_{10} ( r )$$
$${Pin}_{p e a k i n g} = P 1 + 10 ( 1 - r )$$
wherein P1 is a power proportional to the power of the input signal, Pinₘₐᵢₙ and Pin_{peaking} are the input powers of two class-AB PAs, respectively, and 1≥r≥0.

13. The linear power-amplification circuit of claim 12, wherein 1≥r≥0.5.

14. The linear power-amplification circuit of claim 12, wherein two control circuits of the two circuit branches are configured for adjusting bias voltages of the two class-AB PAs, or for adjusting a biasing voltage of a peaking PA of the two class-AB PAs while maintaining a biasing voltage of a main PA of the two class-AB PAs constant.

15. The linear power-amplification circuit of claim 1, wherein at least one circuit branch of the plurality of circuit branches comprises an impedance inverter coupled to an output of the respective class-AB PA.

16. The linear power-amplification circuit of claim 1, wherein the plurality of circuit branches are connected to the output via a matching network.

17. A method, comprising:
introducing a plurality of sets of parameter values of one or more parameters to a linear power-amplification circuit;
for each set of the plurality of sets of parameter values, inputting signals of different powers to the linear power-amplification circuit and determining a set of intermodulation distortion (IMD) values and a set of power-added-efficiency (PAE) values for the each set, thereby obtaining a plurality of sets of IMD values and a plurality of sets of PAE values;
identifying one or more sets of parameter values whose corresponding IMD values within a target power output or power input range are greater than an IMD threshold; and
for each of a plurality of power output or power input values within the target power output or power input range, selecting, from the one or more set of parameter values, a set of parameter values with a greatest PAE value as a determined power-proportionality value for a power output or power input value of the plurality of power output or power input values.

18. The method of claim 17, wherein the one or more parameters comprise at least one of phase-adjustment between circuit branches of the linear power-amplification circuit, or a power proportionality of class-AB PAs of the linear power-amplification circuit.

19. A non-transitory computer readable storage medium having stored thereon computer-executable instructions that, when executed by a computer, cause the computer to perform:
introducing a plurality of sets of parameter values of one or more parameters to a linear power-amplification circuit;
for each set of the plurality of sets of parameter values, inputting signals of different powers to the linear power-amplification circuit and determining a set of intermodulation distortion (IMD) values and a set of power-added-efficiency (PAE) values for the each set, thereby obtaining a plurality of sets of IMD values and a plurality of sets of PAE values;
identifying one or more sets of parameter values whose corresponding IMD values within a target power output or power input range are greater than an IMD threshold; and
for each of a plurality of power output or power input values within the target power output or power input range, selecting, from the one or more set of parameter values, a set of parameter values with a greatest PAE value as a determined power-proportionality value for a power output or power input value of the plurality of power output or power input values.
